(19) United States
(12) Patent Application Publication
(10) Pub. No.: US 2022/0367156 A1
(43) Pub. Date: Nov. 17, 2022

(54) PLASMA PROCESSING APPARATUS AND PLASMA PROCESSING METHOD

(71) Applicant: Hitachi High-Tech Corporation, Minato-ku, Tokyo (JP)

(72) Inventors: Tatsuya Suzuki, Tokyo (JP); Makoto Kashibe, Tokyo (JP)

(21) Appl. No.: 17/278,423

(22) PCT Filed: Feb. 7, 2020
(86) PCT No.: PCT/JP2020/004764

§ 371 Date: Mar. 22, 2021

(51) Int. Cl. H01J 37/32

(52) U.S. Cl. CPC H01J 37/32715; H01J 37/32568; H01J 2237/334; H01J 37/32229; H01J 37/32238; H01J 37/32201

(57) ABSTRACT

At a time of a wafer processing by a plasma processing apparatus, in order to prevent first radio frequency power from being diverted into an output line of a second radio frequency power supply via plasma, the plasma processing apparatus includes: a processing chamber in which a sample is plasma-processed; a sample stage that includes a first electrode and a second electrode disposed outside the first electrode and on which the sample is placed; a first radio frequency power supply configured to supply first radio frequency power to the first electrode via a first matching device and a first transmission path; and a second radio frequency power supply configured to supply second radio frequency power to the second electrode via a second matching device and a second transmission path. The plasma processing apparatus further includes a control device configured to control the first radio frequency power supply to supply the first radio frequency power to the sample stage when a preset value of the second matching device is a predetermined value. The predetermined value is a value that makes an impedance of the second transmission path an impedance at which the radio frequency power is not detected by the second matching device.

### TECHNICAL FIELD

The present invention relates to a plasma processing apparatus and a plasma processing method that process a substrate-shaped sample such as a semiconductor wafer held in a processing chamber inside a vacuum container. The invention particularly relates to a plasma processing apparatus and a plasma processing method that are suitable for processing a sample by forming a bias potential with radio frequency power.

### BACKGROUND ART

In a manufacturing process of a semiconductor device, in order to form a circuit or wiring of the device, a mask formed in advance on an upper surface of a sample such as a semiconductor wafer or a plurality of film layers to be processed are generally etched using plasma.

Recently, with improvement of a degree of integration of semiconductor devices, further improvement of accuracy in such a processing using the plasma is required. In order to increase the yield of devices that can be manufactured for each single wafer, it is required to reduce a region in which a variation in the processing performed on an end portion of the wafer exceeds a tolerance range.

As a preceding technique in the related art, PTL 1 discloses an example for reducing a variation in the processing performed on an end portion of a wafer. The example is a wafer processing method including: disposing a first electrode inside a sample stage; disposing a second electrode on an inner side of a ring-shaped member that is formed of a dielectric and is disposed on an outer peripheral side of the sample stage; and adjusting radio frequency power supplied from first radio frequency power supply to the first electrode and radio frequency power supplied from second radio frequency power supply to the second electrode. In this method, by adjusting the radio frequency power to be supplied to the second electrode to attain a desired electric field distribution in a conductor ring disposed on an outer peripheral side of a wafer, the variation in the processing performed on the end portion of the wafer is reduced.

### CITATION LIST

### Patent Literature

PTL 1: JP-A-2016-225376

### SUMMARY OF INVENTION

### Technical Problem

In the related art described above, the first radio frequency power supply is connected to the first electrode via a first impedance matching device that performs impedance matching of a power supply output line, and the second radio frequency power supply is connected to the second electrode via a second impedance matching device that performs the impedance matching of the power supply output line. The first electrode and the second electrode are connected to each other via plasma.

In this configuration, when the wafer is processed, the radio frequency power output from the first radio frequency power supply is relatively larger than the radio frequency power output from the second radio frequency power supply. Therefore, the first radio frequency power supplied to the first electrode is diverted into the output line of the second radio frequency power supply via the plasma.

When the first radio frequency power is diverted into the output line of the second radio frequency power supply, the diverted power is reflected by the second radio frequency power supply. Reflected power is monitored as traveling power at a monitor value of the second radio frequency power supply.

Such diversion of the power has a larger influence as an output of the second radio frequency power is smaller. The impedance matching device performs impedance matching of the output line when a power monitor value detected by monitoring the output line of the radio frequency power supply is equal to or greater than a predetermined value.

In a case where a power set value set for the second radio frequency power supply is equal to or less than a predetermined value, when diversion of the first radio frequency power is large, the power monitor value obtained by monitoring the output line of the radio frequency power supply exceeds the predetermined value, and the second impedance matching device starts an matching operation.

Since the diverted power is unstable, the matching operation of the second impedance matching device is also unstable. When reproducibility of a matching position is not achieved because the matching operation is unstable, reproducibility of the plasma may not be achieved, and a processing result of the wafer may vary.

An object of the invention is to provide a plasma processing apparatus and a plasma processing method of high quality by preventing a phenomenon in which first radio frequency power is diverted into an output line of a second radio frequency power supply via plasma and preventing variation in a processing result of a wafer.

### Solution to Problem

In order to solve the above problems, the invention provides, as an aspect of the invention, a plasma processing apparatus including: a processing chamber in which a sample is plasma-processed; a sample stage that includes a first electrode and a second electrode disposed outside the first electrode and on which the sample is placed; a first radio frequency power supply configured to supply first radio frequency power to the first electrode via a first matching device and a first transmission path; and a second radio frequency power supply configured to supply second radio frequency power to the second electrode via a second matching device and a second transmission path. The plasma processing apparatus further includes a control device configured to control the first radio frequency power supply to supply the first radio frequency power to the sample stage when a preset value of the second matching device is a predetermined value. The predetermined value is a value that makes an impedance of the second transmission path an impedance at which the radio frequency power is not detected by the second matching device.

The invention provides, as another aspect other than the above, a plasma processing apparatus including: a processing chamber in which a sample is plasma-processed; a sample stage that includes a first electrode and a second electrode disposed outside the first electrode and on which the sample is placed; a first radio frequency power supply configured to supply first radio frequency power to the first electrode via a first matching device and a first transmission path; and a second radio frequency power supply configured to supply second radio frequency power to the second electrode via a second matching device and a second transmission path. The plasma processing apparatus further includes a control device configured to control the first radio frequency power supply to supply the first radio frequency power to the sample stage when a matching position of the second matching device is fixed.

The invention provides, as still another aspect other than the above, a plasma processing apparatus including: a processing chamber in which a sample is plasma-processed; a sample stage that includes a first electrode and a second electrode disposed outside the first electrode and on which the sample is placed; a first radio frequency power supply configured to supply first radio frequency power to the first electrode via a first matching device and a first transmission path; and a second radio frequency power supply configured to supply second radio frequency power to the second electrode via a second matching device and a second transmission path. The plasma processing apparatus further includes a control device configured to control the first radio frequency power supply to supply the first radio frequency power to the sample stage when the second transmission path is disconnected by making a relay connected to the second transmission path non-conducting.

### Advantageous Effect

According to the invention, it is possible to prevent a variation in a processing result of a wafer by preventing a phenomenon in which first radio frequency power is diverted into an output line of a second radio frequency power supply via plasma.

### BRIEF DESCRIPTION OF DRAWINGS

FIG. 1 is a longitudinal cross-sectional view schematically showing an outline of a configuration of a plasma processing apparatus according to first and second embodiments of the invention.

FIG. 2 is a longitudinal cross-sectional view schematically showing an outline of a configuration of a plasma processing apparatus according to a third embodiment of the invention.

FIG. 3 is a diagram showing a control block according to the first and second embodiments.

FIG. 4 is a diagram showing a control block according to the third embodiment.

FIG. 5 is a timing chart showing control timings according to an example in the related art.

FIG. 6 is a timing chart showing control timings according to the first embodiment.

FIG. 7 is a timing chart showing control timings according to the second embodiment.

FIG. 8 is a timing chart showing control timings according to the third embodiment.

FIG. 9 is a diagram showing a table of preset positions of a second matching device corresponding to set power of a first radio frequency power supply according to the second embodiment.

FIG. 10 is a diagram showing a flowchart of a control flow according to the example in the related art.

FIG. 11 is a diagram showing a flowchart of a control flow according to the first embodiment.

FIG. 12 is a diagram showing a flowchart of a control flow according to the second embodiment.

FIG. 13 is a diagram showing a flowchart of a control flow according to the third embodiment.

### DESCRIPTION OF EMBODIMENTS

Hereinafter, first to third embodiments of the invention will be described as embodiments for carrying out the invention with reference to the drawings.

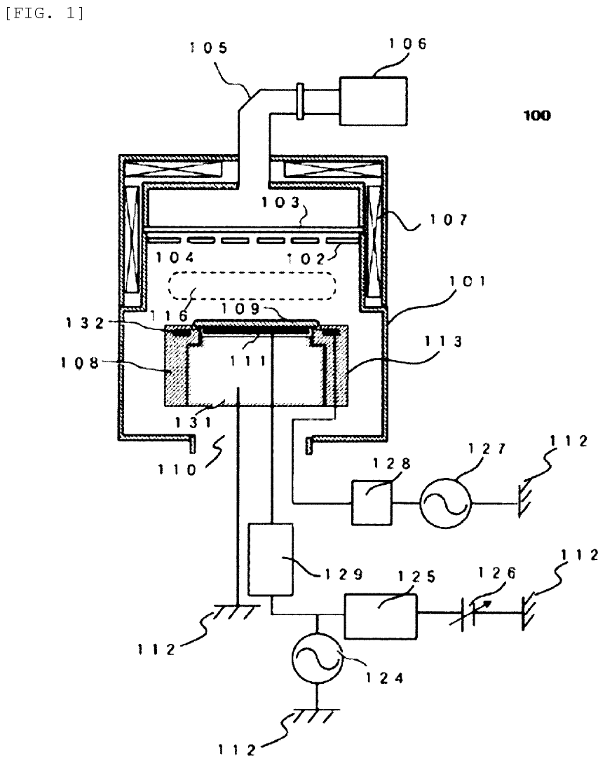

FIG. 1 is a longitudinal cross-sectional view schematically showing an outline of a configuration of a plasma processing apparatus 100 according to the first and second embodiments of the invention.

In the present embodiment, a microwave ECR plasma etching apparatus is used. That is, an electric field having a specific frequency in a microwave band is used as an electric field for forming plasma in a processing chamber, and a magnetic field having an intensity corresponding to the frequency of the electric field is supplied into the processing chamber. By interaction between the electric field and the magnetic field, electron cyclotron resonance (ECR) is generated, and atoms or molecules of a gas supplied into the processing chamber are excited to form plasma, thereby etching a film to be processed on an upper surface of a semiconductor wafer.

A plasma processing apparatus according to the present embodiment includes a vacuum container 101 in which a processing chamber 104 having a cylindrical shape is disposed, a plasma forming unit that is disposed on an upper side and an outer periphery of the vacuum container 101 and supplies an electric field and a magnetic field for forming plasma in the processing chamber 104 in the vacuum container 101, and a vacuum exhaust unit including a roughing vacuum pump such as a turbo molecular pump and a rotary pump that is connected to a lower side of the vacuum container 101 and evacuates an inside of the processing chamber 104.

A dielectric window 103, which has a disc shape and is formed of, for example, quartz, is disposed on an upper portion of the processing chamber 104 to hermetically partition an inside and an outside of the processing chamber 104, and covers the upper portion of the processing chamber 104, thereby forming a ceiling surface thereof.

A shower plate 102 that is formed of a dielectric (for example, quartz) and on which a plurality of through holes are formed to introduce an etching gas is disposed in the processing chamber 104 below the dielectric window 103.

A substantially cylindrical space having a small height in which the supplied etching gas is diffused and filled is formed between the shower plate 102 and the dielectric window 103, and the space is connected to a gas supply device that supplies the etching gas via a gas introduction tube path (not shown).

A vacuum exhaust port 110 communicating with a lower portion of the processing chamber 104 is formed at a lower part of the vacuum container 101, and a vacuum exhaust device (not shown) which is the vacuum exhaust unit including a turbo molecular pump is connected to a lower part of the vacuum exhaust port 110.

A waveguide tube 105 that propagates the electric field to be introduced into the processing chamber 104 is disposed, as the plasma forming unit, above the dielectric window 103. The waveguide tube 105 according to the present embodiment is roughly divided into two portions, and has a cylindrical tube portion that has an axis extending vertically upward above the processing chamber 104 and has a circular cross section, and a prismatic tube portion that is connected to an upper end portion of the cylindrical tube portion, has an axis being oriented from the cylindrical portion and bent to extend in a horizontal direction and has a rectangular cross section.

An electric field generating power supply 106 such as a magnetron that oscillates and forms an electric field of microwave is disposed on an end portion of the prismatic tube portion. The electric field oscillated and formed in the electric field generating power supply 106 is propagated through the waveguide tube 105, enters a cylindrical space for oscillation that is connected to a lower part of a lower end portion of the cylindrical tube portion, and is set to a predetermined mode of the electric field. Then, the electric field passes through the dielectric window 103 and is supplied into the processing chamber 104. Frequency of an electromagnetic wave is not particularly limited, and a microwave of 2.45 GHz is used in the present embodiment.

Further, a magnetic field generating coil 107, which is a solenoidal coil for forming the magnetic field to be supplied into the processing chamber 104, is disposed in a manner of surrounding an upper part and side parts of the processing chamber 104 on an outer peripheral side of the processing chamber 104 of the vacuum container 101.

The electric field that has been propagated and has been introduced inside the processing chamber 104 interacts with the magnetic field that has been formed by the magnetic field generating coil 107 and has been introduced inside the processing chamber 104 to excite particles of the etching gas, which has been supplied similarly into the processing chamber 104. Accordingly, the plasma is generated in the processing chamber 104.

A sample stage 108 is disposed on a lower portion of the processing chamber 104. An upper surface of the sample stage 108 is coated with a dielectric film which is a film formed of a material including a dielectric formed by thermal spraying, and a wafer 109, which is a substrate-shaped sample to be processed, is placed and held on an upper surface of the dielectric film.

A placement surface on which the wafer 109 is placed faces the dielectric window 103 or the shower plate 102. A conductor film 111 formed of a conductor material is disposed inside the dielectric film. The conductor film 111 is connected with a direct current power supply 126 via a radio frequency filter 125, and is formed as a film-shaped electrode.

Further, the sample stage 108 has a substantially cylindrical shape whose axis is aligned with an axis of the processing chamber 104. A base material 131, which has a disc shape and is formed of metal, is disposed inside the sample stage 111 as an electrode to which a first radio frequency power supply 124 is electrically connected via a matching device 129.

A susceptor 113, which is a ring-shaped member formed of a dielectric such as quartz, is disposed on an outer peripheral side of a film (dielectric film) that is formed of a dielectric and has a substantially circular shape in accordance with a shape of the wafer 109 disposed on an upper surface of the base material 131. Thus, a height of the base material 131 is recessed and is small at a place on the outer peripheral side of the dielectric film, which is the placement surface of the sample stage 108, and is stepped from the upper surface of the dielectric film. The susceptor 113 is placed in the ring-shaped recessed portion forming the step. Accordingly, an upper surface and a side surface of the sample stage 108 are covered and protected from the plasma. That is, the susceptor 113 formed of a dielectric functions as a cover for protecting the sample stage 108 from plasma.

In the plasma processing apparatus 100 described above, a vacuum container for transport (not shown) is connected to a side surface of the vacuum container 101 via a gate. The unprocessed wafer 109 passes through the gate and is carried in the processing chamber 104 in a state of being placed and held on an arm of a transport robot disposed inside the vacuum container (vacuum transport container) for transport.

The wafer 109 transported inside the processing chamber 104 is handed over from the arm to the sample stage 108, and is placed on the dielectric film forming the upper surface of the sample stage 108. Thereafter, a direct current voltage is supplied to the conductor film 111 from the direct current power supply 126, and the wafer 109 is adsorbed and held on the dielectric film by an electrostatic force that is formed between the wafer 109 and the conductor film 111. The processing chamber 104 is hermetically blocked with respect to the vacuum transport container by a gate valve (not shown), which opens and closes the gate at the time of the processing, and an inside of the processing chamber 104 is sealed.

Thereafter, a vacuum exhaust device 108 is driven while the etching gas is introduced into the processing chamber 104 from the shower plate 102, and an interior pressure of the processing chamber 104 is maintained at a predetermined pressure according to a balance between a supply rate and an evacuation rate of the gas.

In this state, plasma 116 is formed in the processing chamber 104 by an interaction between the electric field and the magnetic field that are supplied from the plasma forming unit. When the plasma 116 is formed in the processing chamber 104 above the sample stage 108, the radio frequency power is supplied to the base material 131 from the first radio frequency power supply 124 connected to the base material 131 in the sample stage 108, and a bias potential is formed on the dielectric film and the wafer 109 on the upper surface of the sample stage 108.

Charged particles such as ions in the plasma 116 are attracted toward the upper surface of the wafer 109 due to a potential difference between the bias potential and a potential of the plasma 116 and collide with a top surface having a film structure that has been formed in advance on the upper surface of the wafer 109. Accordingly, a film layer to be processed having the film structure that forms a circuit of a semiconductor device disposed on the upper surface of the wafer 109 is etched.

Although not shown, a gas for promotion of heat transfer of helium or the like is introduced into a portion between a rear surface of the wafer 109 and the upper surface of the dielectric film of the sample stage 108 while the etching processing is performed. Heat exchange is promoted between the gas and a coolant flow path which is disposed inside the base material 131 of the sample stage 108 and in which a coolant for cooling flows, so that a temperature of the wafer 109 is adjusted to a value in a range suitable for the processing.

The etching gas and a reaction product generated by the etching are evacuated from the vacuum exhaust port 110 that is formed on a bottom portion of the vacuum container 101 and communicates with the lower portion of the processing chamber 104 and a vacuum pump inlet of the vacuum exhaust device.

When a predetermined etching processing on the film structure of the upper surface of the wafer 109 ends, the supply of the radio frequency power from the first radio frequency power supply 124 is stopped. After the supply of power for the adsorption from the direct current power supply 126 is stopped and the static electricity is removed, the wafer 109 is raised to the upper part of the sample stage 108, and is handed over to the arm of the transport robot, which has passed through the gate opened by the gate valve and has entered the processing chamber 104. Then, the unprocessed wafer 109 is carried into the upper part of the sample stage 108 again.

Thereafter, the unprocessed wafer 109 is placed on the upper part of the sample stage 108 and the processing of the wafer 109 is started. On the other hand, in the case of absence of the unprocessed wafer 109 to be processed, an operation of the plasma processing apparatus 100 for the wafer processing ends, and deactivation or an operation for maintenance is performed.

A heater (not shown) may be disposed on an inner side of the base material 131 having a cylindrical shape of the sample stage 108 or the dielectric film having a disc or circular shape such that the wafer 109 placed on the sample stage 108 or the upper part of the upper surface of the dielectric film is heated to the temperature suitable for the processing.

Then, a heat transfer medium (coolant) with temperature being set to a value in a range of predetermined values by a temperature adjustment device (not shown) flows inside the base material 131 so as to reduce or prevent an increase in temperature of the wafer 109 to be heated by the heater or by being exposed to the plasma 116 during the processing. Therefore, a coolant flow path is concentrically or helically disposed around a center of the base material 131.

Although not shown, a temperature sensor that detects temperature of the base material 131 or the sample stage 108 for the temperature adjustment, a plurality of pins to be lowered to allow the wafer 109 to be spaced apart to the upper part of the dielectric film or to place the wafer on the upper surface of the film, a position sensor of the pins, a connector on a power supply path to the conductor film 111 and the base material 131, and the like are disposed inside the base material 131 of the sample stage 108. There is a concern that those members malfunction under the environment with great electrical noise. There is a concern that the coolant also tinged with the static electricity under the environment with the electrical noise.

In the present embodiment, as shown in the figure, the base material 131 is electrically connected to a ground 112.

A conductor ring 132, which surrounds the wafer 109 or the wafer placement surface of the dielectric film of the upper surface of the base material 131 and is formed of metal, is disposed inside the susceptor 113 according to the present embodiment. The conductor ring 132 is electrically connected with a second radio frequency power supply 127 via a second matching device 128, and functions as an electrode.

The radio frequency power of a predetermined frequency generated from the second radio frequency power supply 127 is introduced to the conductor ring 132 to form the potential above the upper surface of the conductor ring 132 and between the upper surface and the plasma 116. In the configuration shown in FIG. 1, a supply path between the second radio frequency power supply 127 and the conductor ring 132 is disposed at a different location from a supply path between the first radio frequency power supply 124 and the conductor film 111 in the dielectric film.

The first matching device 129 and the second matching device 128 are devices that adjust the impedance of the output lines of the radio frequency power supplies connected to each other to be constant, and a variable element for automatically adjusting a value according to the output power and the state of plasma is adopted. The variable element can change the impedance, and in the present embodiment, a method of setting a min value of the impedance to 0% and a max value of the impedance to 100% is adopted. However, a method of directly managing the impedance value may be adopted.

Further, since the impedance of the power supply output line changes depending on a device configuration, the matching device described above is formed by elements such as a resistor, a coil, and a capacitor. In the present embodiment, an element configuration using a coil is adopted. However, the element configuration of the matching device is preferably adopted in accordance with the device configuration, and an element other than the coil may be adopted.

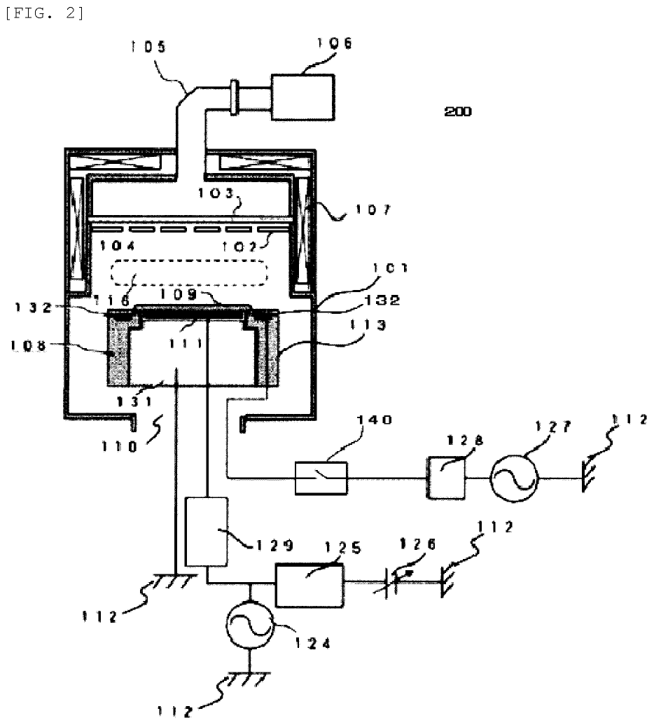

FIG. 2 is a longitudinal cross-sectional view schematically showing an outline of a configuration of a plasma processing apparatus 200 according to the third embodiment of the invention. In the third embodiment, as compared with the configuration of the plasma processing apparatuses according to the first and second embodiments shown in FIG. 1, the second radio frequency power supply 127 and the second matching device 128 introduce the radio frequency power to the conductor ring 132 via a switch circuit represented by a relay 140, as shown in FIG. 2.

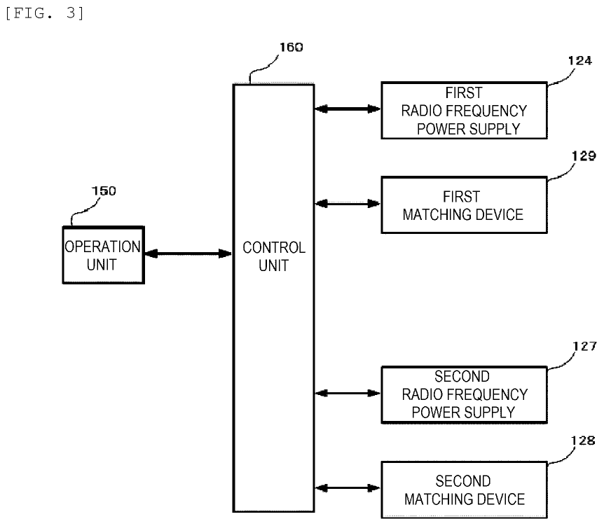

FIG. 3 is a diagram showing a control block according to the first and second embodiments of the invention.

A control unit 160 is connected to an operation unit 150 for an operator to operate the plasma processing apparatus, and includes a CPU, an ROM, and an RAM (all of which are not shown). The control unit 160 is connected to the first radio frequency power supply 124, the first matching device 129, the second radio frequency power supply 127, and the second matching device 128. The CPU provided in the control unit 160 executes a discharge sequence related to the wafer processing in accordance with a control program stored in, for example, the ROM provided in the control unit 160.

The operator inputs processing conditions (a set power Pws value of the first radio frequency power supply 124, a set power Pfs value of the second radio frequency power supply 127, a VL1 value which is a preset position of the first matching device 129, a VL2 value which is a preset position of the second matching device 128, and the like) at the time of processing the wafer to the operation unit 150.

The processing conditions input to the operation unit 150 are stored in the ROM inside the control unit 160. At a timing when the wafer processing is performed, with reference to set values stored in the ROM, the CPU in the control unit 160 sets the set power Pws value of the first radio frequency power supply 124 to the first radio frequency power supply 124, sets the set power Pfs value of the second radio frequency power supply 127 to the second radio frequency power supply 127, sets the VL1 value, which is the preset position of the first matching device 129, to the first matching device 129, and sets the VL2 value, which is the preset position of the second matching device 128, to the second matching device 128.

Then, in order to generate plasma, the first radio frequency power supply 124 and the second radio frequency power supply 127 output the set power value when an RF-ON signal is changed from an OFF state to an ON state. Each matching device adjusts the VL value, which is the preset position, to a predetermined VL value at a set timing.

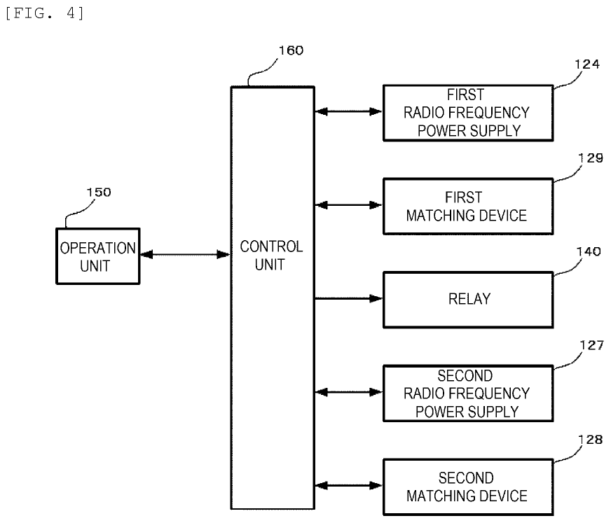

FIG. 4 is a diagram showing a control block according to the third embodiment of the invention.

A configuration according to the third embodiment is different from the configuration according to the first and second embodiments shown in FIG. 3 in that the relay 140 is connected to the control unit 160. The relay 140 cuts off a path that supplies radio frequency power from the second radio frequency power supply 127 to the conductor ring 132.

The relay 140 is a normally-off relay. When the set power Pfs value of the second radio frequency power supply 127 is 0 [W], a relay ON signal for driving the relay changes from an OFF state to an ON state so as to insulate the power supply path between the conductor ring 132 and the second radio frequency power supply 127. Accordingly, the relay 140 is switched from a conductive state to a non-conductive state, and the power supply path to the conductor ring 132 is cut off.

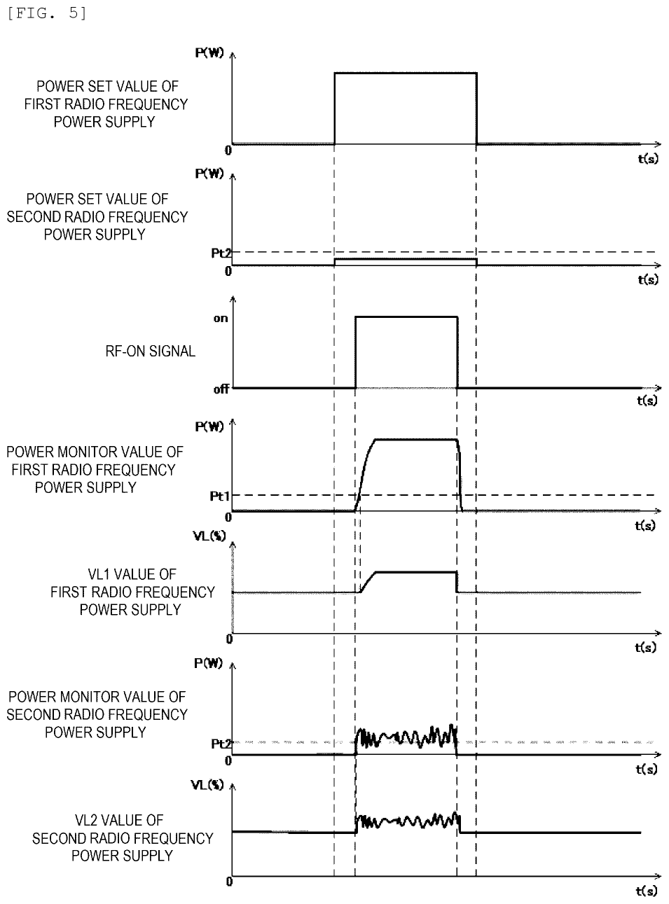

Next, control timings according to an example in the related art and the first to third embodiments will be described in order with reference to timing charts shown in FIGS. 5 to 8.

FIG. 5 is a timing chart showing control timings according to the example in the related art.

At the timing when the wafer processing is performed, the set power Pws value of the first radio frequency power supply 124 is set to the first radio frequency power supply 124, the set power Pfs value of the second radio frequency power supply 127 is set to the second radio frequency power supply 127, the VL1 value which is the set position of the first matching device 129 is set to the first matching device 129, and the VL2 value which is the set position of the second matching device 128 is set to the second matching device 128.

In the example in the related art, since 50% is set as positions of VL1 and VL2, VL1 and VL2 is moved to a position of 50%. A reason why the position is set to 50% is that the impedance that can be matched may be adjusted from a position of 0% to a position of 100% depending on a magnitude of the power output from each radio frequency power supply or a state of the plasma, and a life is limited since wear occurs according to a degree of adjustment.

After each setting is made, when the first radio frequency power supply 124 and the second radio frequency power supply 127 receive that the RF-ON signal is in the ON state, the radio frequency power set from each radio frequency power supply is detected by a power sensor provided in each radio frequency power supply.

Here, when a power value Pwm detected by the first radio frequency power supply 124 exceeds a matching condition Pt1, an impedance adjustment operation starts, and thus the VL1 value of the first matching device 129 starts to move. Then, when the impedance of the power supply output line reaches the predetermined value, the VL1 value converges since the matching condition is satisfied.

The set power Pfs value of the second radio frequency power supply 127 is lower than a matching condition Pt2, but the power value Pfm detected by the second radio frequency power supply 127 exceeds Pt2, and the impedance adjustment operation starts.

The radio frequency power supplied by the first radio frequency power supply 124 to the base material 131, which is an electrode, has a disc shape and is formed of metal, is diverted into the second radio frequency power supply 127 via the plasma and the conductor ring 132. This is because the radio frequency power is reflected by the second radio frequency power supply 127 and is detected as traveling power by the second radio frequency power supply 127.

Since such diversion power is unstable, the impedance of the power supply output line is also unstable, and the VL2 value does not converge.

As described above, there is a concern that, when the impedance of the power supply output line becomes unstable, a state of the plasma serving as a load is also unstable, and a variation in process performance such as an etching rate occurs.

When the wafer processing is completed and the first radio frequency power supply 124 and the second radio frequency power supply 127 receive that the RF-ON signal is in the OFF state, the output of each radio frequency power supply converges to 0 W. Then, the set value of each radio frequency power supply is set to 0 W, and the position of the VL of each matching device is also moved to 50%.

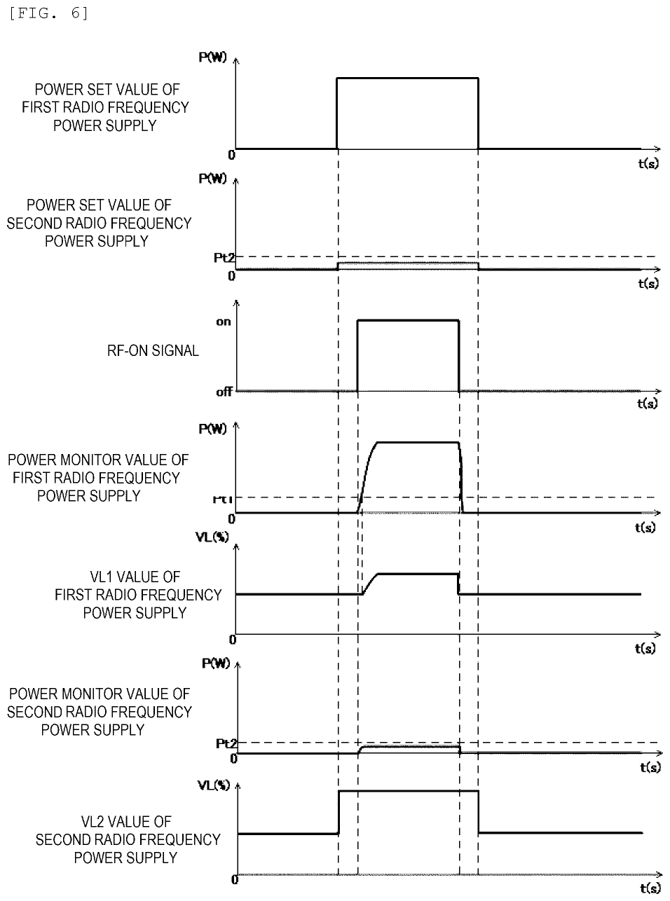

FIG. 6 is a timing chart showing control timings according to the first embodiment.

At the timing when the wafer processing is performed, the set power Pws value of the first radio frequency power supply 124 is set to the first radio frequency power supply 124, the set power Pfs value of the second radio frequency power supply 127 is set to the second radio frequency power supply 127, the VL1 value which is the preset position of the first matching device 129 is set to the first matching device 129, and the VL2 value which is the preset position of the second matching device 128 is set to the second matching device 128.

In the first embodiment, since the set power Pfs value of the second radio frequency power supply 127 is set to a value lower than the matching condition Pt2, 100% is set as the VL2 position of the second matching device 128, and VL2 is moved from a position of 50% to a position of 100%. This is because an impedance of a second radio frequency power supply line is set to be high in advance to prevent the power diverted from the first radio frequency power supply 124 into the second radio frequency power supply line as shown in the example in the related art. Since 50% is set as the VL1 position, VL1 is moved to a position of 50%.

After each setting is made, when the first radio frequency power supply 124 and the second radio frequency power supply 127 receive that the RF-ON signal is in the ON state, the radio frequency power set from each radio frequency power supply is detected by a power sensor provided in each radio frequency power supply.

Here, when a power value Pwm detected by the first radio frequency power supply 124 exceeds a matching condition Pt1, an impedance adjustment operation starts, and thus the VL1 value of the first matching device 129 starts to move. Then, when the impedance of the power supply output line reaches the predetermined value, the VL1 value converges since the matching condition is satisfied.

Since the VL2 position of the second matching device 128 is 100%, and the power diverted from the first radio frequency power supply 124 into the second radio frequency power supply line is prevented, the power value Pfm detected by the second radio frequency power supply 127 does not exceed Pt2, and the impedance adjustment operation does not start.

As described above, when the impedance of the power supply output line is stable, the state of the plasma serving as a load is also stable, and the variation in process performance such as an etching rate can be prevented.

When the wafer processing is completed and the first radio frequency power supply 124 and the second radio frequency power supply 127 receive that the RF-ON signal is in the OFF state, the output of each radio frequency power supply converges to 0 W. Then, the set value of each radio frequency power supply is set to 0 W, and the position of the VL of each matching device is also moved to 50%.

In the first embodiment, the VL2 position is moved to 100%, but a value other than 100% may also be set because it is sufficient to move the VL2 to a position at which the diversion power can be sufficiently prevented. Since the VL2 position is raised from the normal 50%, it is necessary to design the position with sufficient care for a life.

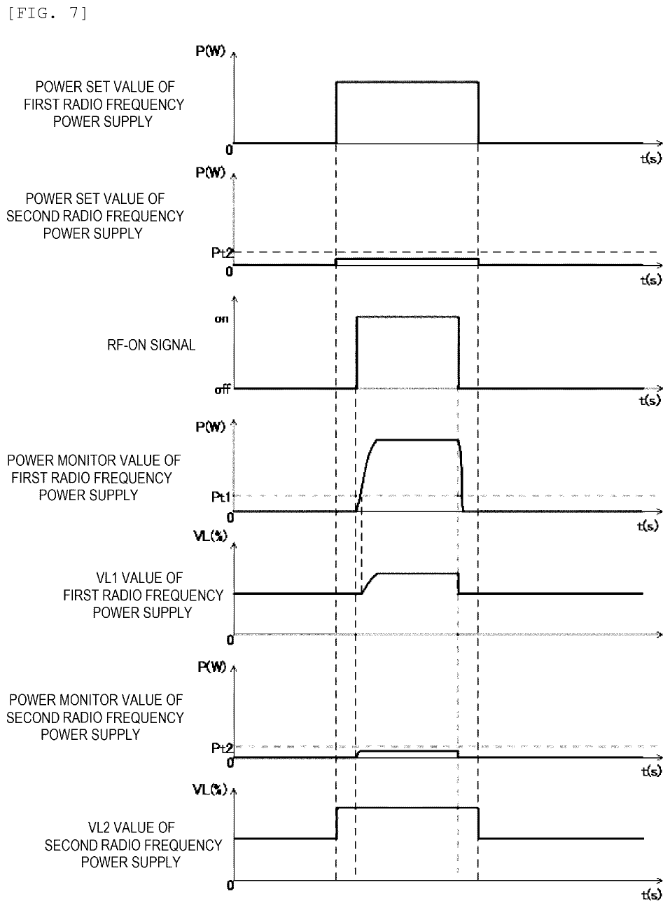

FIG. 7 is a timing chart showing control timings according to the second embodiment.

At the timing when the wafer processing is performed, the set power Pws value of the first radio frequency power supply 124 is set to the first radio frequency power supply 124, the set power Pfs value of the second radio frequency power supply 127 is set to the second radio frequency power supply 127, the VL1 value which is the preset position of the first matching device 129 is set to the first matching device 129, and the VL2 value which is the preset position of the second matching device 128 is set to the second matching device 128.

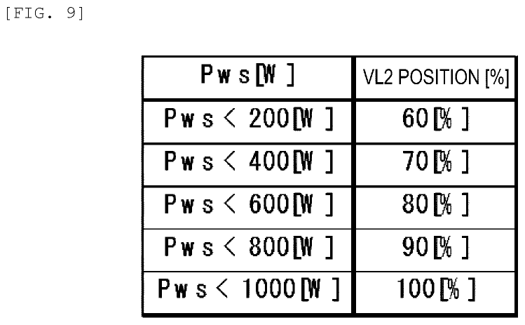

FIG. 9 shows a table of the VL2 position, which is the preset position of the second matching device 128, corresponding to the set power Pws value of the first radio frequency power supply 124 according to the second embodiment. In the second embodiment, since the set power Pfs value of the second radio frequency power supply 127 is set to a value lower than the matching condition Pt2, the VL2 of the second matching device 128 is moved to the VL2 position corresponding to the table of the VL2 position shown in FIG. 9. This is because an impedance of a second radio frequency power supply line is set to be high in advance to prevent the power diverted from the first radio frequency power supply 124 into the second radio frequency power supply line as shown in the example in the related art.

Since the power diverted into the second radio frequency power supply line increases according to the magnitude of the set power Pws of the first radio frequency power supply 124, the VL2 value at which the diversion with respect to the magnitude of Pws can be prevented is determined with reference to the correspondence table shown in FIG. 9. On the other hand, since 50% is set as the VL1 position, VL1 is moved to a position of 50%.

After each setting is made, when the first radio frequency power supply 124 and the second radio frequency power supply 127 receive that the RF-ON signal is in the ON state, the radio frequency power set from each radio frequency power supply is detected by a power sensor provided in each radio frequency power supply.

Here, when the power value Pwm detected by the first radio frequency power supply 124 exceeds the matching condition Pt1, the impedance adjustment operation starts, and thus the VL1 value of the first matching device 129 starts to move. Then, when the impedance of the power supply output line reaches the predetermined value, the VL1 value converges since the matching condition is satisfied.

The VL2 value of the second matching device 128 is a value corresponding to the table shown in FIG. 9, and prevents the power diverted from the first radio frequency power supply 124 to the second radio frequency power supply line. Therefore, the power value Pfm detected by the second radio frequency power supply 127 does not exceed Pt2, and the impedance adjustment operation does not start.

As described above, when the impedance of the power supply output line is stable, the state of the plasma serving as a load is also stable, and the variation in process performance such as an etching rate can be prevented.

When the wafer processing is completed and the first radio frequency power supply 124 and the second radio frequency power supply 127 receive that the RF-ON signal is in the OFF state, the output of each radio frequency power supply converges to 0 W.

The set value of each radio frequency power supply is set to 0 W, and the position of the VL of each matching device is also moved to 50%. In the second embodiment, since the VL2 position is raised from the normal 50%, it is necessary to design the position with sufficient care for a life.

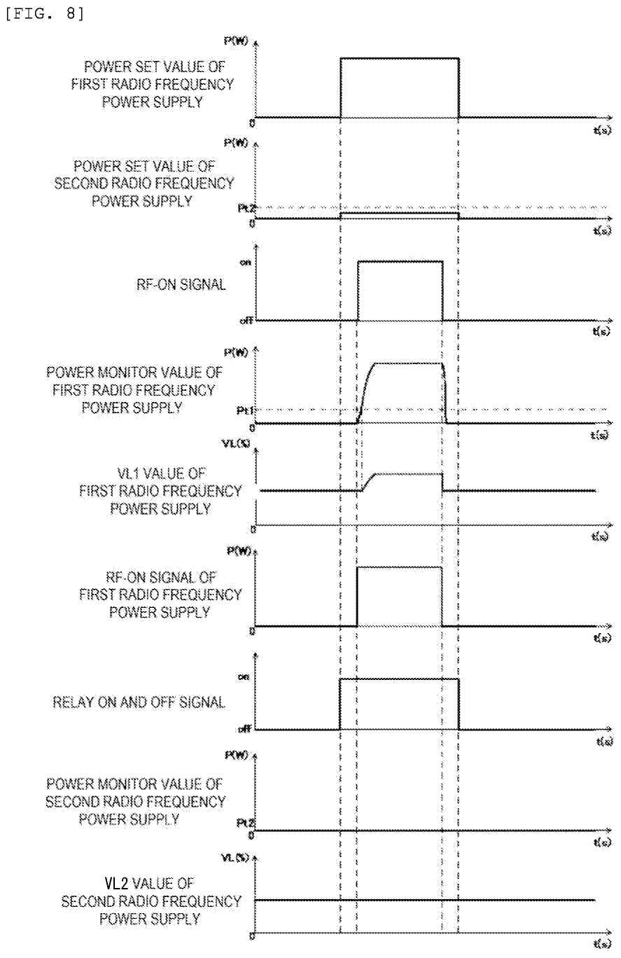

FIG. 8 is a timing chart showing control timings according to the third embodiment.

At the timing when the wafer processing is performed, the set power Pws value of the first radio frequency power supply 124 is set to the first radio frequency power supply 124, the set power Pfs value of the second radio frequency power supply 127 is set to the second radio frequency power supply 127, the VL1 value which is the preset position of the first matching device 129 is set to the first matching device 129, and the VL2 value which is the preset position of the second matching device 128 is set to the second matching device 128.

In the third embodiment, since the set power Pfs value of the second radio frequency power supply 127 is set to 0 W, a relay ON and OFF signal is in an ON state, and the normally-off relay 140 is turned from the conductive state to the non-conductive state. This is because the second radio frequency power supply line is disconnected by the relay 140 to cut off the power diverted from the first radio frequency power supply 124 to the second radio frequency power supply line as shown in the example in the related art. Since 50% is set as the VL1 position, VL1 is moved to a position of 50%.

After each setting is made, when the first radio frequency power supply 124 and the second radio frequency power supply 127 receive that the RF-ON signal is in the ON state, the radio frequency power set from each radio frequency power supply is detected by a power sensor provided in each radio frequency power supply.

Here, when the power value Pwm detected by the first radio frequency power supply 124 exceeds the matching condition Pt1, the impedance adjustment operation starts, and thus the VL1 value of the first matching device 129 starts to move. Then, when the impedance of the power supply output line reaches the predetermined value, the VL1 value converges since the matching condition is satisfied.

Since the VL2 value of the second matching device 128 cuts off and prevents the power diverted from the first radio frequency power supply 124 to the second radio frequency power supply line by the relay 140, the power value Pfm detected by the second radio frequency power supply 127 remains at 0 W. Therefore, since Pfm does not exceed Pt2, the impedance adjustment operation does not start.

As described above, when the impedance of the power supply output line is stable, the state of the plasma serving as a load is also stable, and the variation in process performance such as an etching rate can be prevented.

When the wafer processing is completed and the first radio frequency power supply 124 and the second radio frequency power supply 127 receive that the RF-ON signal is in the OFF state, the output of the first radio frequency power supply converges to 0 W.

Then, the set value of the first radio frequency power supply is set to 0 W, and the VL1 position of the first matching device 129 is also moved to 50%.

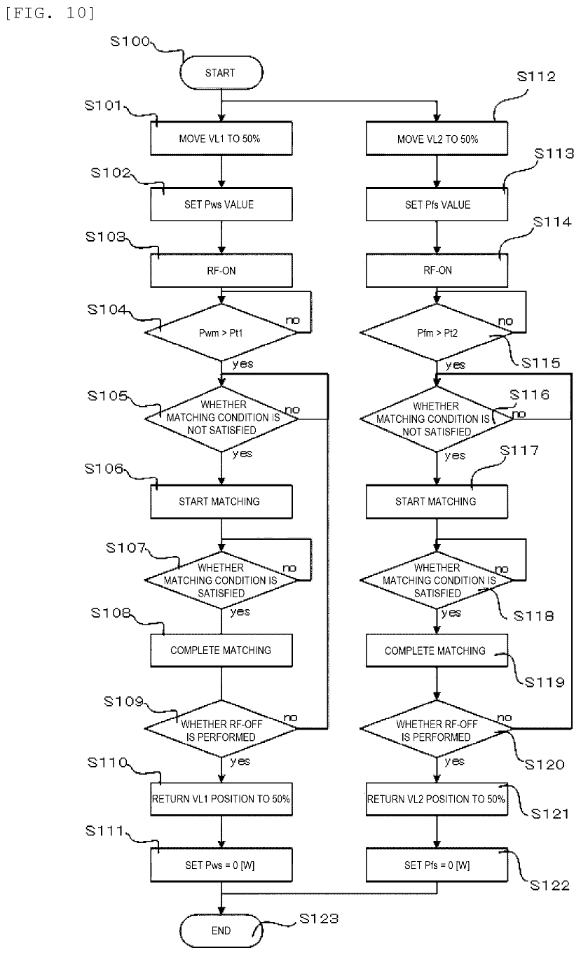

Next, a control flow according to the example in the related art and the first to third embodiments will be described in order with reference to flowcharts shown in FIGS. 10 to 13. In both the example in the related art and the first to third embodiments, a main body that executes the control flow is the control unit 160, and thus the description of the main body will be omitted below.

FIG. 10 is a flowchart showing a control flow according to the example in the related art.

Step 101 (S101) to step 111 (S111), which are the control flow shown on a left side in FIG. 10, are control flows of the first radio frequency power supply and the matching device.

On the other hand, step 112 (S112) to step 122 (S122), which are the control flows shown on a right side in FIG. 10, are the control flows of the second radio frequency power supply and the matching device.

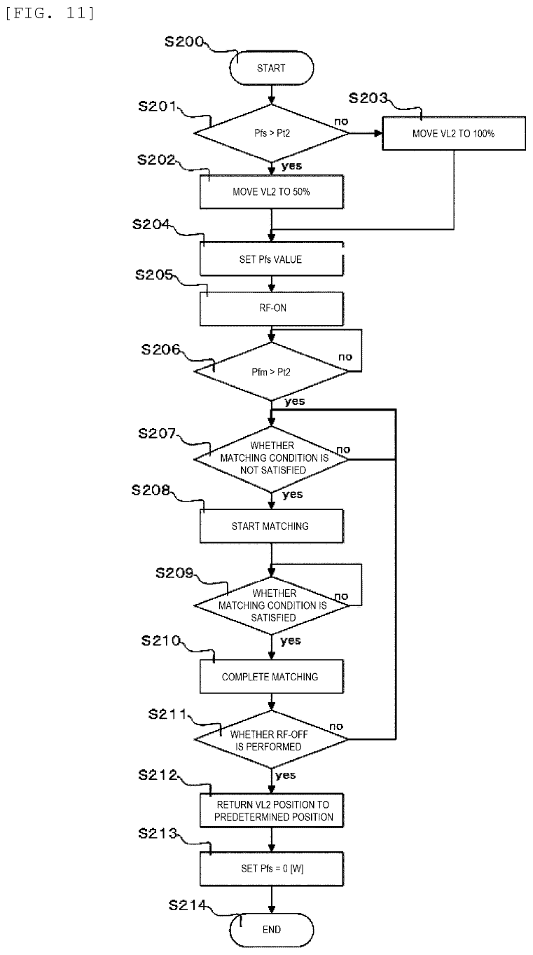

Among these, since the control flow of the first radio frequency power supply and the matching device executed in step 101 (S101) to step 111 (S111) is the same in the flowcharts shown in FIGS. 11 to 13 respectively according to the first to third embodiments to be described later, notations in the flowcharts shown in FIGS. 11 to 13 and description thereof will be omitted.

In step 100 (S100), a discharge sequence at the time of the wafer processing is started.

First, the control flow of the first radio frequency power supply and the matching device will be described. As described above, the control flow of the first radio frequency power supply and the matching device is the same in the first to third embodiments.

In step 101 (S101), the VL1 position of the first matching device 129 is moved to 50%.

In step 102 (S102), the set power Pws value is set to the first radio frequency power supply 124.

In step 103 (S103), the RF-ON signal is changed from the OFF state to the ON state.

In step 104 (S104), it is determined whether the electric power Pwm detected by the first radio frequency power supply 124 is larger than Pt1.

When it is determined that the detected power Pwm is smaller than Pt1 (no), determination in step 104 (S104) is repeated. When it is determined that the detected power Pwm is larger than Pt1 (yes), the process proceeds to step 105 (S105).

In step 105 (S105), it is determined whether the matching condition of the first matching device 129 is not satisfied (whether the impedance of the first radio frequency power supply line is not a predetermined value).

When it is determined that the matching condition of the first matching device 129 is satisfied (no), determination in step 105 (S105) is repeated. When it is determined that the matching condition of the first matching device 129 is not satisfied (yes), the process proceeds to step 106 (S106).

In step 106 (S106), the matching operation of the first matching device 129 is started.

In step 107 (S107), it is determined whether the matching condition of the first matching device 129 is satisfied (whether the impedance of the first radio frequency power supply line is a predetermined value).

When it is determined that the matching condition of the first matching device 129 is not satisfied (no), determination in step 107 (S107) is repeated. When it is determined that the matching condition of the first matching device 129 is satisfied (yes), the process proceeds to step 108 (S108).

In step 108 (S108), the matching operation of the first matching device 129 ends.

In step 109 (S109), it is determined whether the RF-ON signal is in the OFF state (whether RF-OFF is performed).

When it is determined that the RF-ON signal is not in the OFF state (RF-OFF is not performed) (no), the process returns to step 105 (S105). When it is determined that the RF-ON signal is in the OFF state (RF-OFF is performed) (yes), the VL1 position of the first matching device 129 is returned to 50% in step 110 (S110).

In step 111 (S111), the set power Pws of the first radio frequency power supply 124 is set to 0 W.

In step 123 (S123), the control flow of the first radio frequency power supply and the matching device ends.

Next, a control flow of the second radio frequency power supply and the matching device will be described.

In step 112 (S112), the VL2 position of the second matching device 128 is moved to 50%.

In step 113 (S113), the set power Pfs value is set to the second radio frequency power supply 127.

In step 114 (S114), the RF-ON signal is changed from the OFF state to the ON state.

In step 115 (S115), it is determined whether the power Pfm detected by the second radio frequency power supply 127 is larger than Pt2.

When it is determined that the detected power Pfm is smaller than Pt2 (no), determination in step 115 (S115) is repeated. When it is determined that the detected power Pfm is larger than Pt2 (yes), the process proceeds to step 116 (S116).

In step 116 (S116), it is determined whether the matching condition of the second matching device 128 is not satisfied (whether the impedance of the second radio frequency power supply line is not a predetermined value).

When it is determined that the matching condition of the second matching device 128 is satisfied (no), determination in step 116 (S116) is repeated. When it is determined that the matching condition of the second matching device 128 is not satisfied (yes), the matching operation of the second matching device 128 is started in step 117 (S117).

In step 118 (S118), it is determined whether the matching condition of the second matching device 128 is satisfied (whether the impedance of the second radio frequency power supply line is a predetermined value).

When it is determined that the matching condition of the second matching device 128 is not satisfied (no), determination in step 116 (S116) is repeated. When it is determined that the matching condition of the second matching device 128 is satisfied (yes), the matching operation of the second matching device 128 ends in step 119 (S119).

In step 120 (S120), it is determined whether the RF-ON signal is in the OFF state (whether RF-OFF is performed).

When it is determined that the RF-ON signal is not in the OFF state (RF-OFF is not performed), the process returns to step 116 (S116). When it is determined that the RF-ON signal is in the OFF state (RF-OFF is performed), the VL2 position of the second matching device 128 is returned to 50% in step 121 (S121).

In step 122 (S122), the set power Pfs of the second radio frequency power supply 127 is set to 0 W.

In step 123 (S123), the control flow of the second radio frequency power supply and the matching device ends.

FIG. 11 is a diagram showing a flowchart of the control flow (limited to the control flow of the second radio frequency power supply and the matching device) according to the first embodiment.

In step 200 (S200), the discharge sequence at the time of the wafer processing is started.

In step 201 (S201), it is determined whether the Pfs value set to the second radio frequency power supply 127 is larger than Pt2.

When it is determined that the set power Pfs value is smaller than Pt2 (no), the VL2 position is moved to 100% in step 203 (S203). When it is determined that the set power Pfs value is larger than Pt2 (yes), the VL2 position is moved to 50% in step 202 (S202).

In step 204 (S204), the set power Pfs value is set to the second radio frequency power supply 127.

In step 205 (S205), the RF-ON signal is changed from the OFF state to the ON state.

In step 206 (S206), it is determined whether the power Pfm detected by the second radio frequency power supply 127 is larger than Pt2.

When it is determined that the detected power Pfm is smaller than Pt2 (no), determination in step 206 (S206) is repeated. When it is determined that the detected power Pfm is larger than Pt2 (yes), it is determined in step 207 (S207) whether the matching condition of the second matching device 128 is satisfied (whether the impedance of the second radio frequency power supply line is not a predetermined value).

When it is determined that the matching condition of the second matching device 128 is satisfied (no), determination in step 207 (S207) is repeated. When it is determined that the matching condition of the second matching device 128 is not satisfied (yes), the matching operation of the second matching device 128 is started in step 208 (S208).

In step 209 (S209), it is determined whether the matching condition of the second matching device 128 is satisfied (whether the impedance of the second radio frequency power supply line is a predetermined value).

When it is determined that the matching condition of the second matching device 128 is not satisfied (no), determination in step 209 (S209) is repeated. When it is determined that the matching condition of the second matching device 128 is satisfied (yes), the matching operation of the second matching device 128 ends in step 210 (S210).

In step 211 (S211), it is determined whether the RF-ON signal is in the OFF state (whether RF-OFF is performed).

When it is determined that the RF-ON signal is not in the OFF state (RF-OFF is not performed) (no), the process returns to step 207 (S207). When it is determined that the RF-ON signal is in the OFF state (RF-OFF is performed) (yes), the VL2 position of the second matching device 128 is returned to the predetermined position in step 212 (S212).

In step 213 (S213), the set power Pfs of the second radio frequency power supply 127 is set to 0 W.

In step 214 (S214), the control flow of the second radio frequency power supply and the matching device ends.

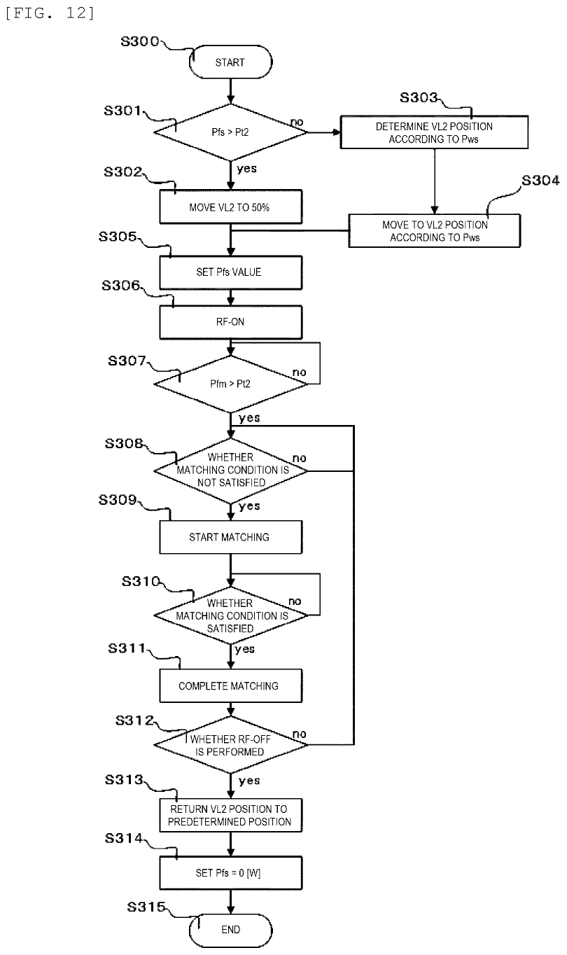

FIG. 12 is a diagram showing a flowchart of the control flow (limited to the control flow of the second radio frequency power supply and the matching device) according to the second embodiment.

In step 300 (S300), the discharge sequence at the time of the wafer processing is started.

In step 301 (S301), it is determined whether the Pfs value set to the second radio frequency power supply 127 is larger than Pt2.

When it is determined that the set power Pfs value is smaller than Pt2 (no), the set position of VL2 corresponding to the set power Pws of the first radio frequency power supply 124 is determined with reference to the table of the VL2 position shown in FIG. 9 in step 303 (S303).

In step 304 (S304), the VL2 is moved to the VL2 position determined in step 303 (S303), and the process proceeds to step 305 (S305).

When it is determined that the set power Pfs value is larger than Pt2 (yes), the VL2 position is moved to 50% in step 302 (S302).

In step 305 (S305), the set power Pfs value is set to the second radio frequency power supply 127.

In step 306 (S306), the RF-ON signal is changed from the OFF state to the ON state.

In step 307 (S307), it is determined whether the power Pfm detected by the second radio frequency power supply 127 is larger than Pt2.

When it is determined that the detected power Pfm is smaller than Pt2 (no), determination in step 307 (S307) is repeated. When it is determined that the detected power Pwm is larger than Pt2 (yes), it is determined in step 308 (S308) whether the matching condition of the second matching device 128 is not satisfied (whether the impedance of the second radio frequency power supply line is not a predetermined value).

When it is determined that the matching condition of the second matching device 128 is satisfied (no), determination in step 308 (S308) is repeated. When it is determined that the matching condition of the second matching device 128 is not satisfied (yes), the matching operation of the second matching device 128 is started in step 309 (S309).

In step 310 (S310), it is determined whether the matching condition of the second matching device 128 is satisfied (whether the impedance of the second radio frequency power supply line is a predetermined value).

When it is determined that the matching condition of the second matching device 128 is not satisfied (no), determination in step 310 (S310) is repeated. When it is determined that the matching condition of the second matching device 128 is satisfied (yes), the matching operation of the second matching device 128 ends in step 311 (S311).

In step 312 (S312), it is determined whether the RF-ON signal is in the OFF state (whether RF-OFF is performed).

When it is determined that the RF-ON signal is not in the OFF state (RF-OFF is not performed) (no), the process returns to step 308 (S308). When it is determined that the RF-ON signal is in the OFF state (RF-OFF is performed) (yes), the VL2 position of the second matching device 128 is returned to the predetermined position in step 313 (S313).

In step 314 (S314), the set power Pfs of the second radio frequency power supply 127 is set to 0 W.

In step 315 (S315), the control flow of the second radio frequency power supply and the matching device ends.

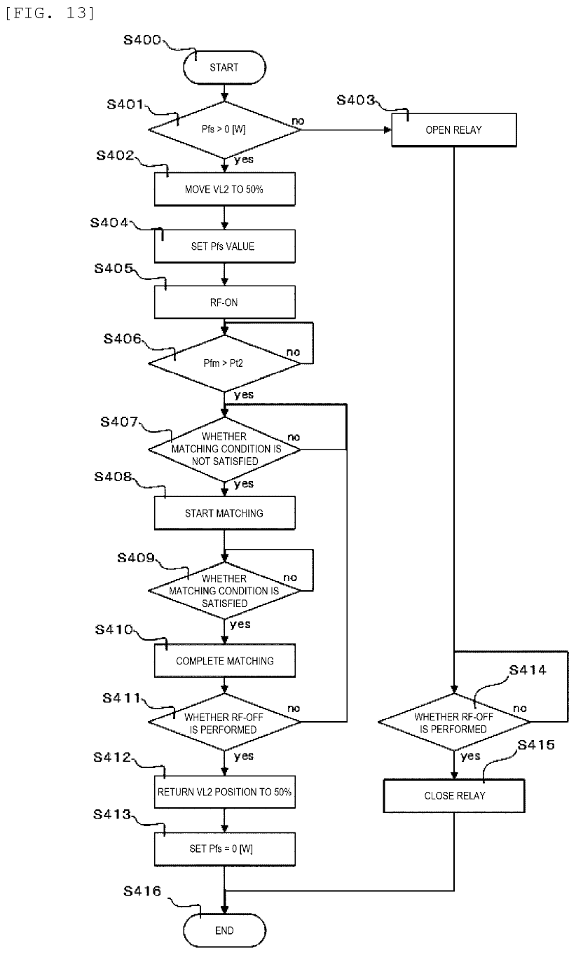

FIG. 13 is a diagram showing a flowchart of the control flow (limited to the control flow of the second radio frequency power supply and the matching device) according to the third embodiment.

In step 400 (S400), the discharge sequence at the time of the wafer processing is started.

In step 401 (S401), it is determined whether the Pfs value set to the second radio frequency power supply 127 is larger than 0 W.

When it is determined that the set power Pfs value is 0 W (no), the relay 140 is changed from the conductive state to the non-conductive state in step 403 (S403), and the process proceeds to step 414 (S414).

In step 414 (S414), it is determined whether the RF-ON signal is in the OFF state (whether RF-OFF is performed).

When it is determined that the RF-ON signal is not in the OFF state (RF-OFF is not performed) (no), step 414 (S414) is repeated. When it is determined that the RF-ON signal is in the OFF state (RF-OFF is performed) (yes), the relay 140 is changed from the non-conductive state to the conductive state in step 415 (S415), and the process proceeds to step 416 (S416).

On the other hand, when it is determined in step 401 (S401) that the set power Pfs value is larger than 0 W (yes), the VL2 position is moved to 50% in step 402 (S402).

In step 404 (S404), the set power Pfs value is set to the second radio frequency power supply 127.

In step 405 (S405), the RF-ON signal is changed from the OFF state to the ON state.

In step 406 (S406), it is determined whether the power Pfm detected by the second radio frequency power supply 127 is larger than Pt2.

When it is determined that the detected power Pfm is smaller than Pt2 (no), determination in step 406 (S406) is repeated. When it is determined that the detected power Pwm is larger than Pt2 (yes), it is determined in step 407 (S407) whether the matching condition of the second matching device 128 is not satisfied (whether the impedance of the second radio frequency power supply line is not a predetermined value).

When it is determined that the matching condition of the second matching device 128 is satisfied (no), determination in step 407 (S407) is repeated. When it is determined that the matching condition of the second matching device 128 is not satisfied (yes), the matching operation of the second matching device 128 is started in step 408 (S408).

In step 409 (S409), it is determined whether the matching condition of the second matching device 128 is satisfied (whether the impedance of the second radio frequency power supply line is a predetermined value).

When it is determined that the matching condition of the second matching device 128 is not satisfied (no), determination in step 409 (S409) is repeated. When it is determined that the matching condition of the second matching device 128 is satisfied (yes), the matching operation of the second matching device 128 ends in step 410 (S410).

In step 411 (S411), it is determined whether the RF-ON signal is in the OFF state (whether RF-OFF is performed).

When it is determined that the RF-ON signal is not in the OFF state (RF-OFF is not performed) (no), the process returns to step 407 (S407). When it is determined that the RF-ON signal is in the OFF state (RF-OFF is performed) (yes), the VL2 position of the second matching device 128 is returned to 50% in step 412 (S412).

In step 413 (S413), the set power Pfs of the second radio frequency power supply 127 is set to 0 W.

In step 416 (S416), the control flow of the second radio frequency power supply and the matching device ends.

As described above, the invention in a case where the radio frequency voltage is applied to the conductor film 111 from the first radio frequency power supply 124 and the radio frequency voltage is applied to the conductor ring 132 from the second radio frequency power supply 127 has been described above in the first to third embodiment. However, even when the conductor film is divided into a central portion of the base material 131 and an outer peripheral portion of the base material 131 inside the base material 131, a radio frequency voltage is applied from the first radio frequency power supply 124 to the conductor film disposed in the central portion of the base material 131, and a radio frequency voltage is applied from the second radio frequency power source 127 to the conductor film disposed on the outer peripheral portion of the base material 131, the invention described as the first to third embodiments can be applied.

### REFERENCE SIGN LIST

101 . . . vacuum container
102 . . . shower plate
103 . . . dielectric window
104 . . . processing chamber
105 . . . waveguide tube
106 . . . electric field generating power supply
107 . . . magnetic field generating coil
108 . . . sample stage
109 . . . wafer
110 . . . vacuum exhaust port
111 . . . conductor film
112 . . . ground
113 . . . susceptor
116 . . . plasma
124 . . . first radio frequency power supply
125 . . . radio frequency filter
126 . . . direct current power supply
127 . . . second radio frequency power supply
128 . . . second matching device
129 . . . first matching device
131 . . . base material
132 . . . conductor ring
140 . . . relay
150 . . . operation unit
160 . . . control unit

1. A plasma processing apparatus including: a processing chamber in which a sample is plasma-processed; a sample stage that includes a first electrode and a second electrode disposed outside the first electrode and on which the sample is placed; a first radio frequency power supply configured to supply first radio frequency power to the first electrode via a first matching device and a first transmission path; and a second radio frequency power supply configured to supply second radio frequency power to the second electrode via a second matching device and a second transmission path, wherein
the plasma processing apparatus further comprises a control device configured to control the first radio frequency power supply to supply the first radio frequency power to the sample stage when a preset value of the second matching device is a predetermined value, and
the predetermined value is a value that makes an impedance of the second transmission path an impedance at which radio frequency power is not detected by the second matching device.

2. A plasma processing apparatus including: a processing chamber in which a sample is plasma-processed; a sample stage that includes a first electrode and a second electrode disposed outside the first electrode and on which the sample is placed; a first radio frequency power supply configured to supply first radio frequency power to the first electrode via a first matching device and a first transmission path; and a second radio frequency power supply configured to supply second radio frequency power to the second electrode via a second matching device and a second transmission path, wherein
the plasma processing apparatus further comprises a control device configured to control the first radio frequency power supply to supply the first radio frequency power to the sample stage when a matching position of the second matching device is fixed.

3. A plasma processing apparatus including: a processing chamber in which a sample is plasma-processed; a sample stage that includes a first electrode and a second electrode disposed outside the first electrode and on which the sample is placed; a first radio frequency power supply configured to supply first radio frequency power to the first electrode via a first matching device and a first transmission path; and a second radio frequency power supply configured to supply second radio frequency power to the second electrode via a second matching device and a second transmission path, wherein
the plasma processing apparatus further comprises a control device configured to control the first radio frequency power supply to supply the first radio frequency power to the sample stage when the second transmission path is disconnected by making a relay connected to the second transmission path non-conducting.

4. The plasma processing apparatus according to claim 1, wherein
the sample stage further includes a dielectric cover that covers a side surface so as not to be exposed to plasma, and
the second electrode is disposed inside the dielectric cover.

5. The plasma processing apparatus according to claim 1, wherein
the first electrode and the second electrode are disposed inside a base material of the sample stage.

6. A plasma processing method for plasma-processing a sample using a plasma processing apparatus, the plasma processing apparatus including: a processing chamber in which the sample is plasma-processed; a sample stage that includes a first electrode and a second electrode disposed outside the first electrode and on which the sample is placed; a radio frequency power supply configured to supply first radio frequency power to the first electrode via a first matching device and a first transmission path; and a second radio frequency power supply configured to supply second radio frequency power to the second electrode via a second matching device and a second transmission path, wherein
the first radio frequency power is supplied to the sample stage when a preset value of the second matching device is a predetermined value, and
the predetermined value is a value that makes an impedance of the second transmission path an impedance at which the radio frequency power is not detected by the second matching device.

7. The plasma processing method according to claim 6, wherein
the sample stage further includes a dielectric cover that covers a side surface so as not to be exposed to plasma, and
the second electrode is disposed inside the dielectric cover.

8. The plasma processing method according to claim 6, wherein
the first electrode and the second electrode are disposed inside a base material of the sample stage.
